(19) United States
(12) Patent Application Publication
(10) Pub. No.: US 2019/0182949 A1
(43) Pub. Date: Jun. 13, 2019

(54) FLEXIBLE PRINTED CIRCUIT BOARD AND OPTICAL MODULE

(71) Applicant: SUMITOMO ELECTRIC INDUSTRIES, LTD., Osaka-shi (JP)

(72) Inventors: Taichi Misawa, Osaka-shi (JP); Shunsuke Sato, Osaka-shi (JP); Yasushi Fujimura, Osaka-shi (JP)

(21) Appl. No.: 16/217,186

(22) Filed: Dec. 12, 2018

(30) Foreign Application Priority Data
Dec. 13, 2017 (JP) 2017-238686

(51) Int. Cl. H05K 1/02; H05K 1/11; G02B 6/42

(52) U.S. Cl. CPC H05K 1/0251; H05K 1/118; H05K 1/117; H05K 1/116; H05K 1/0246; H05K 2201/09609; G02B 6/4271; H05K 2201/09672; H05K 2201/097; H05K 2201/09709; G02B 6/4281

(57) ABSTRACT

A flexible printed circuit board includes: a board having a top surface and a back surface; a signal line on the top surface; a ground line on the back surface and overlapping with the signal line; a first signal terminal extending along a first direction in the top surface, the first signal terminal including a first via-hole and electrically connected with the signal line; a first ground terminal next to the first signal terminal along a second direction intersecting the first direction on the top surface, the first ground terminal including a second via-hole electrically connected with the ground line; and a second ground terminal next to the first signal terminal in a side opposite to the first ground terminal along the second direction on the top surface, the second ground terminal including a third via-hole electrically connected with the ground line.

### CROSS-REFERENCE TO RELATED APPLICATIONS

This application claims the priority benefit of Japanese Application No. JP2017-238686 filed on Dec. 13, 2017, the disclosures of which are hereby incorporated by reference in its entirety.

### TECHNICAL FIELD

This disclosure relates to a flexible printed circuit board and an optical module.

### BACKGROUND

Japanese Unexamined Patent Publication No. 2015-216385 describes a technology for a printed interconnection board. This printed interconnection board includes a base substrate, a plurality of pads for electrical connection arranged on one surface side of the base substrate and a plurality of interconnections respectively connected to the plurality of pads. A plurality of pads are arranged in a staggered arrangement of two rows back and forth.

Japanese Unexamined Patent Publication No. 2016-46338 describes a technology of a flexible printed circuit board. This flexible printed circuit board includes a film-like insulating base material, a first terminal formed on an end of a film-like insulating base material, a second terminal formed on the other end of the film-like insulating base material, a conductor pattern formed on the film-like insulating and electrically connecting the first terminal with the second terminal, and a film-like insulating coat film covering a predetermined portion of the conductor pattern. The first terminal and the second terminal are formed on both surfaces of the film-like insulating base material, and the terminals on both surfaces are electrically connected with each other through a via hole penetrating the film-like insulating base material.

Japanese Unexamined Patent Publication No. 2014-96424 describes a light-emitting module having an external connecting terminal connected with a flexible printed circuit board.

### SUMMARY

In recent years, a flexible printed circuit board has been used for various applications. One of those applications is an application for transmitting a high frequency signal. For example, a flexible printed circuit board, which connects with a light-emitting module or light-receiving module in an optical communication system, transmits a high frequency transmission or reception signal. In the application of transmitting the high frequency signal, it is important to suppress attenuation of the signal as much as possible. For this reason, it is effective to provide a signal line on one surface of a flexible board and a ground pattern on the other surface to configure a microstrip line. Since a connecting part of the flexible printed circuit board on only any one surface of the board is connected with an optical module or the like, it is effective to configure a so-called coplanar line in which ground terminals (ground lines) are arranged both sides of a signal terminal (signal line).

One the other hand, as electrical equipment is reduced in size and complexed in recent years, an interconnection density of the signal lines in the flexible printed circuit board is increasing. For example, in the light-emitting module or light-receiving module used in the optical communication system, the number of electrical signals input to or output from one module is increasing because of multiplexing of optical signals associated with increase in an information and communication amount. Therefore, also in the flexible printed circuit board connected with the light-emitting module or light-receiving module, an interconnection density of signal lines transmitting transmission signals or received signals is increasing.

However, the signal terminal and the ground terminal are arranged to be aligned at the connecting part of the flexible printed circuit board as described above, and therefore, if the density of the signal lines is increased, a distance between the signal terminal and the ground terminal is narrowed. If the distance between the signal terminal and the ground terminal is narrowed, a coupling capacitance of the signal terminal and the ground terminal increases to lead to decrease in a characteristic impedance. If the characteristic impedance is decreased, a high frequency characteristic of the flexible printed circuit board is degraded to attenuate the signal.

One aspect of this disclosure relates to a flexible printed circuit board includes: a board having a top surface and a back surface; a signal line provided on the top surface of the board; a ground line provided on the back surface and overlapping with the signal line; a first signal terminal extending along a first direction in the top surface of the board, the first signal terminal including a first via-hole and electrically connected with the signal line; a first ground terminal provided next to the first signal terminal along a second direction intersecting the first direction on the top surface of the board, the first ground terminal including a second via-hole electrically connected with the ground line in the back surface of the board; and a second ground terminal provided next to the first signal terminal in a side opposite to the first ground terminal along the second direction on the top surface of the board, the second ground terminal including a third via-hole electrically connected with the ground line in the back surface of the board, wherein the first to third via holes are staggeringly disposed along the second direction.

### BRIEF DESCRIPTION OF THE DRAWINGS

The foregoing and other purposes, aspects and advantages will be better understood from the following detailed description of embodiments of the invention with reference to the drawings, in which:

FIG. 1 is a plan view illustrating an end portion of a flexible printed circuit board according to an embodiment of the disclosure;

FIG. 2 is a bottom plan view illustrating the end portion of the flexible printed circuit board;

FIG. 3 is a perspective view enlargedly illustrating the end portion of the flexible printed circuit board, where illustrated is an outer appearance of the flexible printed circuit board seen from a top surface side;

FIG. 4 is a perspective view enlargedly illustrating the end portion of the flexible printed circuit board, where illustrated is an outer appearance of the flexible printed circuit board seen from a back surface side;

FIG. 5A is a cross-sectional view along a line Va-Va illustrated in FIG. 4, and FIG. 5B is a cross-sectional view along a line Vb-Vb illustrated in FIG. 4;

FIG. 6 is a diagram enlargedly illustrating a land and a surrounding thereof;

FIG. 7 is a partial enlarged view of FIG. 2;

FIG. 8 is a plan view of an optical module including the flexible printed circuit board;

FIG. 9 is a plan view illustrating an inner configuration of the optical module without an upper lid of a chassis;

FIG. 10 is a cross-sectional view along a line X-X illustrated in FIG. 9;

FIG. 11 is a plan view enlargedly illustrating a connecting portion of the flexible printed circuit board and a feed-through;

FIG. 12 is a plan view illustrating an end portion (connecting part) of a flexible printed circuit board of prior art; and

FIG. 13 is a diagram illustrating a state where a width of conductive films for each of a signal terminal and a ground terminal are thinned to widen a distance between the signal terminal and the ground terminal.

### DETAILED DESCRIPTION

### Description of Embodiment of the Disclosure

Firstly, a description is given of contents of embodiments of the present disclosure in a listing manner. A flexible printed circuit board according to an embodiment comprises a substrate which is flexible and insulative, and has a top surface and back surface, a signal line provided on a top surface, a ground pattern provided on the back surface at a position opposed to the signal line, a first signal terminal extending in a first direction on the top surface and being electrically connected with the signal line, a second signal terminal on the back surface being electrically connected with the first signal terminal through one or more first via holes, first and second ground terminals provided respectively on both sides of the second signal terminal in a second direction intersecting the first direction on the back surface, and extending in the first direction and being electrically connected with the ground pattern, and third and fourth ground terminals provided respectively on both sides of the second signal terminal in the second direction on the top surface, and being electrically connected with the first and second ground terminals through one or more second via holes, wherein a position of the first via hole on the first and second signal terminals and positions of the second via holes on the first to fourth ground terminals are displaced from each other in the first direction, and interconnection widths in the second direction of the first and second signal terminals and the first to fourth ground terminals are thinner than an outer diameter of a land provided around each of the first and second via holes.

In general, the via hole needs to have a certain size of inner diameter so that a metal as the conductive film is easily inserted into an inner side thereof. An area (the land) having a certain size of width from the inner wall of the via hole is secured for the conductive film provided around the via hole. In order to prevent a coupling capacitance of the signal terminal and the ground terminal from increasing, it is effective to thin the interconnection widths of the signal terminal and the ground terminal to widen a distance between the signal terminal and the ground terminal. However, if a distance between the land of the signal terminal and the land of the ground terminal is shorter, the whole coupling capacitance cannot be sufficiently suppressed due to capacitive coupling of these lands.

In order to address such a problem, in the above flexible printed circuit board, the position of the first via hole on the first and second signal terminals and the positions of the second via holes on the first to fourth ground terminals are displaced from each other in the first direction. This can make the distance between the land of the signal terminal and the land of the ground terminal be longer to decrease the coupling capacitance of the lands. Therefore, according to the above flexible printed circuit board, it is possible to prevent the increase in the coupling capacitances of the signal terminal and the ground terminal which is involved by the increase in the interconnection density of the signal lines, and effectively suppress decrease in the characteristic impedance.

In the above flexible printed circuit board, the first via hole on the first and second signal terminals and the second via holes on the first to fourth ground terminals may be alternately arranged in the first direction. This allows the land of the signal terminal and the land of the ground terminal to be arranged away from each other to prevent a short caused by contacting. In this case, the distances between the lands of the first and second signal terminals and the lands of the first to fourth ground terminals next to the former lands may be equal to each other.

In the above flexible printed circuit board, the number of first via holes on the first and second signal terminals may be less than the number of via holes on the first and third ground terminals and the number of via holes on the second and fourth ground terminals.

In the above flexible printed circuit board, the position of the second via holes on the first and third ground terminals in the first direction may match the position of the second via holes on the second and fourth ground terminals in the first direction.

An optical module according to another embodiment includes any flexible printed circuit board described above, and a chassis having an external board in which an optical element is mounted and a plurality of interconnections being electrically connected with the optical element are provided. A plurality of interconnections on the external board electrically connect with the first signal terminal on the top surface, and the third and fourth ground terminals. According to the optical module, since any flexible printed circuit board described above is included, it is possible to prevent the increase in the coupling capacitances of the signal terminal and the ground terminal which is involved by the increase in the interconnection density of the signal lines, and effectively suppress decrease in the characteristic impedance.

### Detailed Description of Embodiment of the Disclosure

Next, embodiment according to the present disclosure will be described as referring to accompanying drawings. The present disclosure, however, is not restricted to the embodiment and has a scope defined in claims attached hereto and all changes and/or modifications with the scope and equivalent there to. In the description of the drawings, numerals or symbols same with or similar to each other will refer to elements same with or similar to each other without overlapping explanations.

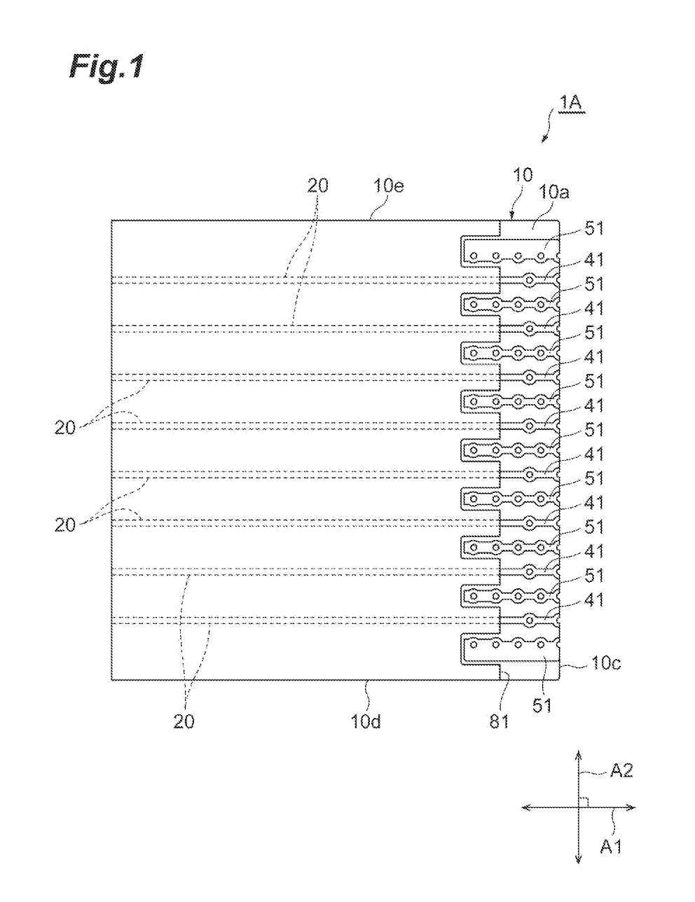

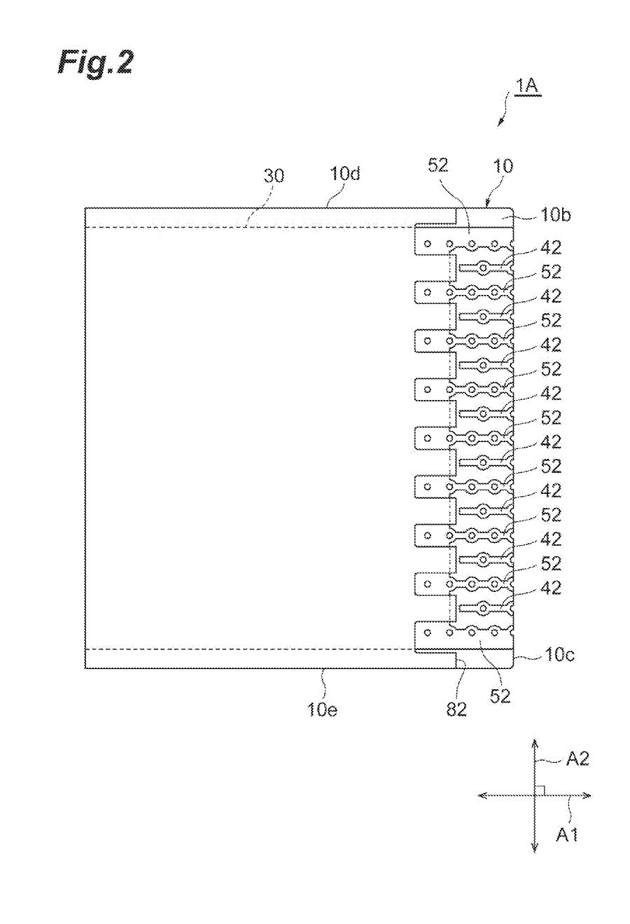

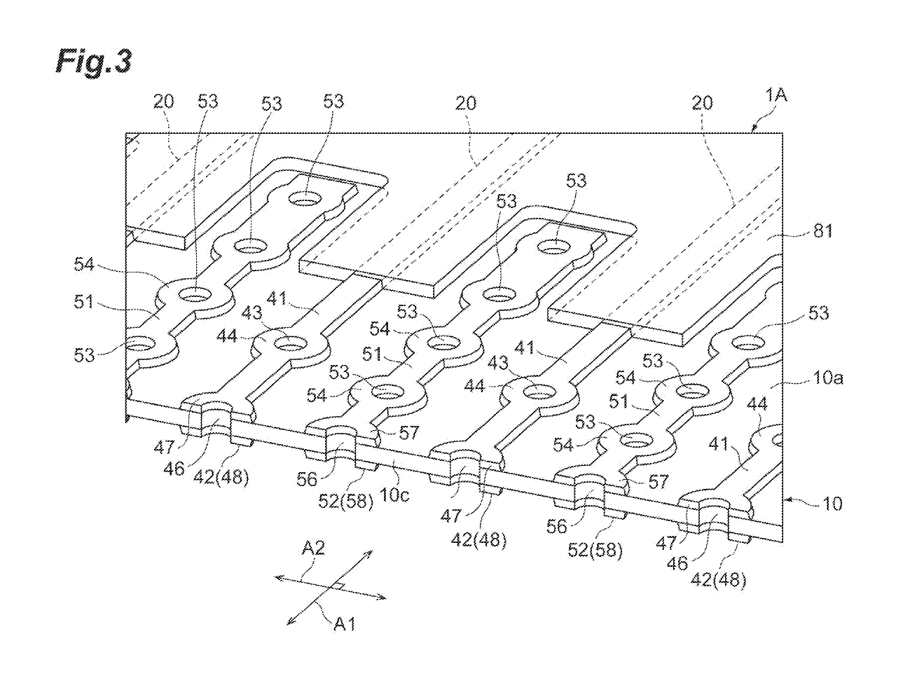

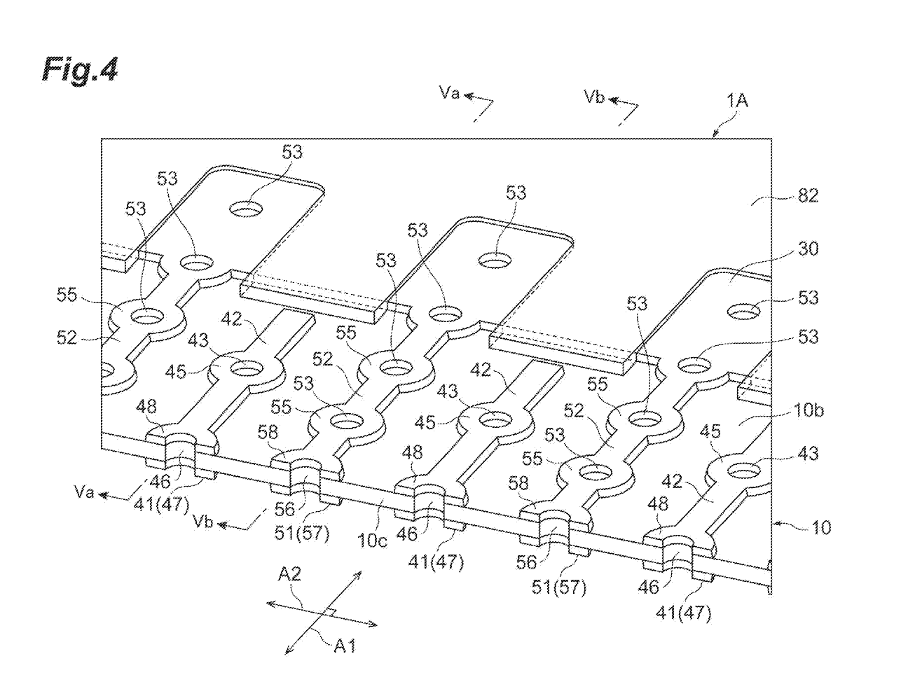

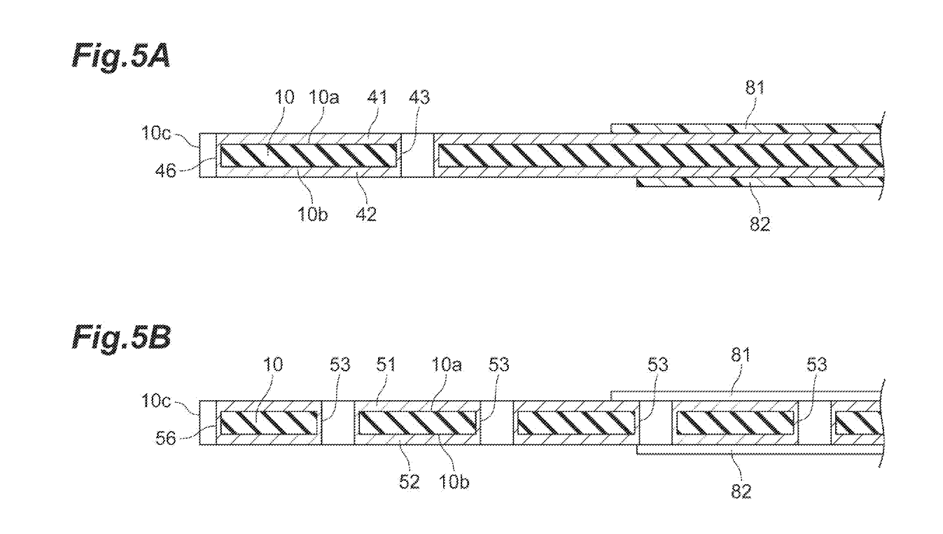

FIG. 1 is a plan view illustrating an end portion of a flexible printed circuit board 1A according to an embodiment of the disclosure. FIG. 2 is a bottom plan view illustrating the end portion of the flexible printed circuit board 1A. FIG. 3 is a perspective view enlargedly illustrating the end portion of the flexible printed circuit board 1A, where illustrated is an outer appearance of the flexible printed circuit board 1A seen from a side of a top surface 10a. FIG. 4 is a perspective view enlargedly illustrating the end portion of the flexible printed circuit board 1A, where illustrated is an outer appearance of the flexible printed circuit board 1A seen from a side of a back surface 10b. FIG. 5A is a cross-sectional view along a line Va-Va illustrated in FIG. 4. FIG. 5B is a cross-sectional view along a line Vb-Vb illustrated in FIG. 4.

As illustrated in FIG. 1 to FIG. 5B, the flexible printed circuit board 1A in the embodiment comprises a plate 10, N signal lines 20 (N is an integer equal to or more than 2, and the embodiment illustrates a case of N=8), a ground pattern 30, N first signal terminals 41, N second signal terminals 42, (N+1) ground terminals 51, (N+1) ground terminals 52, and overlays 81 and 82.

The plate 10 consists of a flexible and insulative material, for example, a dielectric material such as polyimide. The plate 10 extends like a flat substrate along a plane including a first direction A1 and a second direction A2 intersecting (e.g., perpendicular to) each other, and has a flat top surface 10a and a flat back surface 10b positioned opposite to the top surface 10a. A planar shape seen in a thickness direction of the plate 10 is substantially rectangular, and the plate 10 further has a linear end edge 10c extending along the second direction A2, and a pair of side edges 10d and 10e extending from both ends of the end edge 10c along the first direction A1.

The signal line 20 is a conductive film provided on the top surface 10a. As illustrated in FIG. 1 and FIG. 3, N signal lines 20 respectively extend in the first direction A1 and are arranged parallel to each other in the second direction A2. The signal line 20 consists of a metal material, for example, copper (Cu). The signal line 20 extends from one end portion to the other end portion of the flexible printed circuit board 1A in the first direction A1. The signal line 20 transmits a high frequency signal which is output from or input to electrical equipment connected to the end portion of the flexible printed circuit board 1A. A frequency of the high frequency signal is 40 GHz or more, for example.

The ground pattern 30 is a conductive film provided on the back surface 10b. The ground pattern 30 is provided on the back surface 10b at a position opposed to the N signal lines 20. In other words, the ground pattern 30 is layered with N signal lines 20 when seen in the thickness direction of the plate 10. As illustrated in FIG. 2, the ground pattern 30 in the embodiment is formed as one film covering from one side edge 10d to the other side edge 10e of the plate 10 on the back surface 10b. The ground pattern 30 consists of a metal material, for example, copper (Cu). The ground pattern 30 and the signal lines 20 constitute microstrip lines.

Each of N signal terminals 41 is a conductive film provided on the top surface 10a. N signal terminals 41 extend in the first direction A1 on the top surface 10a and are aligned in the second direction A2. N signal terminals 41 electrically connect with N signal lines 20 respectively. N signal terminals 41 are provided to electrically connect N signal lines 20 of the flexible printed circuit board 1A with N signal lines of the electrical equipment via an electrically conductive adhesive such as solder. As illustrated in FIG. 1 and FIG. 3, each signal terminal 41 continuously extends from the corresponding signal line 20 in the first direction A1. Each signal terminal 41 consists of the same metal material as the signal line 20, for example, and is integrally formed with the corresponding signal line 20. Each signal terminal 41 has one end connected to the signal line 20, and the other end reaching the end edge 10c of the plate 10.

Each of N signal terminals 42 is a conductive film provided on the back surface 10b. N signal terminals 42 extend in the first direction A1 on the back surface 10b and are aligned in the second direction A2. As illustrated in FIG. 2 and FIG. 4, each signal terminal 42 is provided on a position opposed to each signal terminal 41. In other words, the signal terminal 41 and the signal terminal 42 are layered with each other when seen in the thickness direction of the plate 10. The signal terminal 42 consists of the same metal material as the signal terminal 41, for example. The signal terminal 42 has one end facing the ground pattern 30, and the other end reaching the end edge 10c of the plate 10.

The signal terminal 42 electrically connects with signal terminal 41 through one or more first via holes 43 (one via hole in the embodiment). The via hole 43 is a hole for electrically connecting the signal terminal 41 and the signal terminal 42 with each other, and penetrates the plate 10 from the top surface 10a to the back surface 10b. A planar shape of the via hole 43 is a circle, for example. On an inner wall of the via hole 43, a metal film electrically connecting the signal terminal 41 with the signal terminal 42 is formed. As illustrated in FIG. 3, a land 44 is provided surrounding the via hole 43 on the top surface 10a. As illustrated in FIG. 4, a land 45 is provided surrounding the via hole 43 on the back surface 10b. The lands 44 and 45 are metal films formed on the top surface 10a and the back surface 10b, respectively. A planar shape of each of lands 44 and 45 is a circular annular shape centered on the via hole 43, for example. The lands 44 and 45 are respectively and integrally formed with the signal terminals 41 and 42.

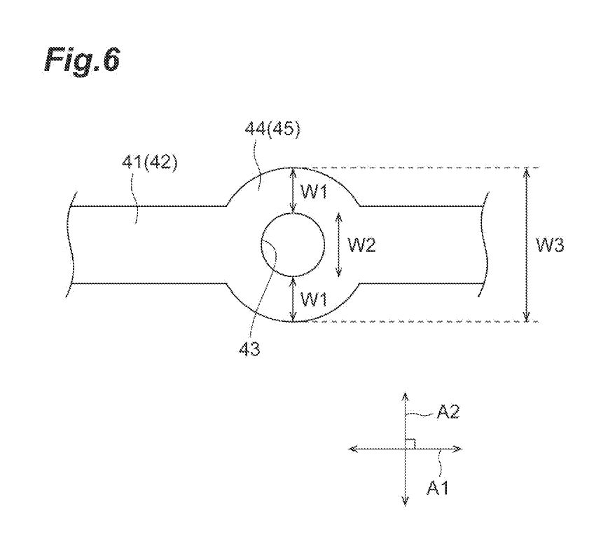

FIG. 6 is a diagram enlargedly illustrating the land 44 (45) and a surrounding thereof. As illustrated in FIG. 6, interconnection widths of the respective signal terminals 41 and 42 in a direction (i.e., the second direction A2) intersecting a longitudinal direction are thinner than outer diameters of the respective lands 44 and 45. In an example, a width W1 from the inner wall of the via hole 43 to an outer perimeter of the land 44 or 45 is 60 μm, a diameter W2 of the via hole 43 is 100 μm, and an outer diameter W3 of the land 44 or 45 is 220 μm.

The plate 10 has a semi-circular cutout 46 on the end edge 10c (see FIG. 3 and FIG. 4) when seen in the thickness direction of the plate 10. The cutout 46 is a portion for electrically connecting the signal terminal 41 with the signal terminal 42, and extends from the top surface 10a to the back surface 10b. On an inner wall of the cutout 46, a metal film electrically connecting the signal terminal 41 with the signal terminal 42 is formed. As illustrated in FIG. 3, a land 47 is provided surrounding the cutout 46 on the top surface 10a. As illustrated in FIG. 4, a land 48 is provided surrounding the cutout 46 on the back surface 10b. The lands 47 and 48 are metal films formed on the top surface 10a and the back surface 10b, respectively. A planar shape of each of lands 47 and 48 is a semi-circular annular shape centered on the cutout 46, for example. The lands 47 and 48 are respectively and integrally formed with the signal terminals 41 and 42.

The ground terminal 51 is a conductive film provided on the top surface 10a. The ground terminal 51 is provided on both sides of each signal terminal 41 in the second direction A2 on the top surface 10a. In the embodiment, (N+1) ground terminals 51 are aligned alternately with N signal terminals 41 in the second direction A2. One of the ground terminals 51 provided on both sides of a signal terminal 41 corresponds to a third ground terminal in the embodiment, and the other corresponds to a fourth ground terminal in the embodiment. A distance between centers (pitch) of the signal terminal 41 and the ground terminal 51 is 380 μm or less, for example. These ground terminals 51 extend along the first direction A1. The ground terminal 52 is a conductive film provided on the back surface 10b. The ground terminal 52 is provided on both sides of each signal terminal 42 in the second direction A2 on the back surface 10b. In the embodiment, (N+1) ground terminals 52 are aligned alternately with N signal terminals 42 in the second direction A2. One of the ground terminals 52 provided on both sides of a signal terminal 42 corresponds to a first ground terminal in the embodiment, and the other corresponds to a second ground terminal in the embodiment. A distance between centers (pitch) of the signal terminal 42 and the ground terminal 52 is 380 μm or less, for example. These ground terminals 52 extend along the first direction A1, and electrically connect with ground pattern 30. The ground terminal 52 electrically connects with the ground terminal 51 through one or more second via holes 53 (four via holes in the embodiment). The ground terminals 51 and 52 are provided to electrically connect with the ground pattern 30 of the flexible printed circuit board 1A with a ground interconnection of the electrical equipment via an electrically conductive adhesive such as solder.

As illustrated in FIG. 2 and FIG. 4, the ground terminals 52 continuously extend from the ground pattern 30 in the first direction A1. The ground terminals 52 consist of the same metal material as the ground pattern 30, for example, and are integrally formed with the ground pattern 30. Each ground terminal 52 has one end connected to the ground pattern 30, and the other end reaching the end edge 10c of the plate 10. The ground terminals 52 are aligned alternately with the signal terminals 42 in the second direction A2. Specifically, one ground terminal 52 is arranged between the signal terminals 42 next to each other, and one signal terminal 42 is arranged between the ground terminals 52 next to each other.

As illustrated in FIG. 1 and FIG. 3, each ground terminal 51 is provided on a position opposed to each ground terminal 52. In other words, the ground terminal 52 and the ground terminal 51 are layered with each other when seen in the thickness direction of the plate 10. The ground terminals 51 extend along the first direction A1. The ground terminal 51 consists of the same metal material as the ground terminal 52, for example. Each ground terminal 51 has one end on a side opposite to the end edge 10c of the plate 10, and the other end reaching the end edge 10c. One end of each ground terminal 51 is positioned between the signal lines 20. The ground terminals 51 are aligned alternately with the signal terminals 41 in the second direction A2. Specifically, one ground terminal 51 is arranged between the signal terminals 41 next to each other, and one signal terminal 41 is arranged between the ground terminals 51 next to each other.

The via hole 53 is a hole for electrically connecting the ground terminal 51 and the ground terminal 52 with each other, and penetrates the plate 10 from the top surface 10a to the back surface 10b. A planar shape of the via hole 53 is a circle, for example. On an inner wall of the via hole 53, a metal film electrically connecting the ground terminal 51 with the ground terminal 52 is formed. As illustrated in FIG. 3, a land 54 is provided surrounding the via hole 53 on the top surface 10a. As illustrated in FIG. 4, a land 55 is provided surrounding the via hole 53 on the back surface 10b. The lands 54 and 55 are metal films formed on the top surface 10a and the back surface 10b, respectively. A planar shape of each of lands 54 and 55 is a circular annular shape centered on the via hole 53, for example. The lands 54 and 55 are respectively and integrally formed with the ground terminals 51 and 52.

A shape of the lands 54 and 55, and surrounding thereof is the same as the shape of the lands 44 and 45, and surrounding thereof illustrated in FIG. 6. Specifically, widths of the ground terminals 51 and 52 in the direction (i.e., the second direction A2) intersecting the longitudinal direction are thinner than outer diameters of the lands 54 and 55, respectively. In an example, a width from the inner wall of the via hole 53 to an outer perimeter of the land 54 or 55 is 60 μm, a diameter of the via hole 53 is 100 μm, and an outer diameter of the land 54 or 55 is 220 μm.

The plate 10 further has a semi-circular cutout 56 on the end edge 10c (see FIG. 3 and FIG. 4) when seen in the thickness direction of the plate 10. The cutout 56 is a portion for electrically connecting the ground terminal 51 with the ground terminal 52, and extends from the top surface 10a to the back surface 10b. On an inner wall of the cutout 56, a metal film electrically connecting the ground terminal 51 with the ground terminal 52 is formed. As illustrated in FIG. 3, a land 57 is provided surrounding the cutout 56 on the top surface 10a. As illustrated in FIG. 4, a land 58 is provided surrounding the cutout 56 on the back surface 10b. The lands 57 and 58 are metal films formed on the top surface 10a and the back surface 10b, respectively. A planar shape of each of lands 57 and 58 is a semi-circular annular shape centered on the cutout 56, for example. The lands 57 and 58 are respectively integrally formed with the ground terminals 51 and 52.

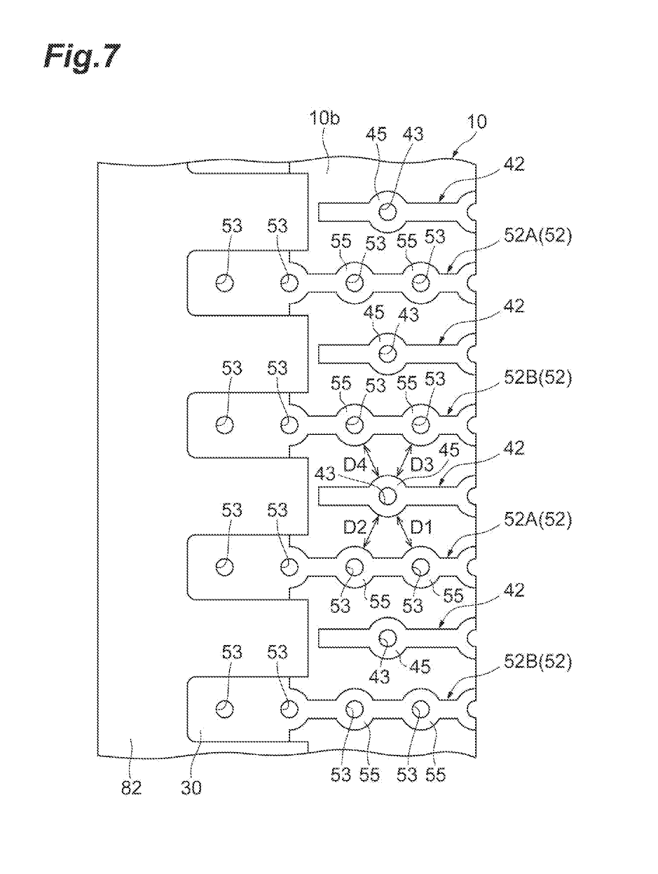

In the embodiment, as illustrated in FIG. 1 to FIG. 4, positions of the via hole 43 and the via hole 53 which are next to each other are displaced from each other in the first direction A1. In other words, the via hole 43 and the via hole 53 are alternately arranged (alternated with each other) in the first direction A1 to configure a staggered arrangement. Such a form is further described with reference to FIG. 7 that is a partial enlarged view of FIG. 2.

The configuration describe above may be considered as that in which a first ground terminal 52A and a second ground terminal 52B arranged on both sides of each signal terminal 42 in the second direction A2. Assuming that the number of via holes 43 formed on each signal terminal 42 is K and the number of via holes 53 formed on each of the ground terminals 52A and 52B is Q (where, K is an integer equal to or more than 1 and Q is an integer equal to or more than 2), Q>K holds. As an example, a case of K=1 and Q=4 is illustrated in FIG. 7. Positions where the via holes 53 are formed on the first ground terminal 52A in the first direction A1 respectively match (coincide with) positions where the via holes 53 are formed on the second ground terminal 52B in the first direction A1. In other words, the positions where the via holes 53 are formed on the first ground terminal 52A and the positions where the via holes 53 are formed on the second ground terminal 52B are line-symmetric with respect to a center line of the signal terminal 42.

Here, assume that distances between the land 45 on the signal terminal 42 and two lands 55 on the first ground terminal 52A next to the land 45 are D1 and D2, respectively. Assume that distances between the land 45 on the signal terminal 42 and two lands 55 on the second ground terminal 52B next to the land 45 are D3 and D4, respectively. In the embodiment, the distances D1 to D4 are equal to each other. Specifically, the distances between the land 45 and all the lands 55 next to the land 45 and of the first and second ground terminals 52A and 52B are equal to each other. This also holds for the land 44 on the signal terminal 42 and the lands 54 next to the land 44 and of the first and second ground terminals 52A and 52B.

The overlays 81 and 82 are films made of a resin (e.g., a resist). The overlay 81 is provided on the top surface 10a of the plate 10 to collectively cover N signal lines 20. The overlay 82 is provided on the back surface 10b of the plate 10 to cover entirely the ground pattern 30.

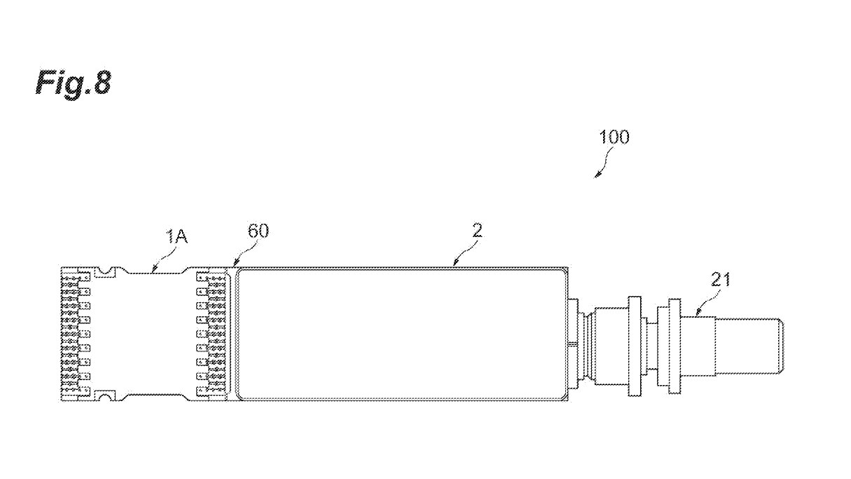

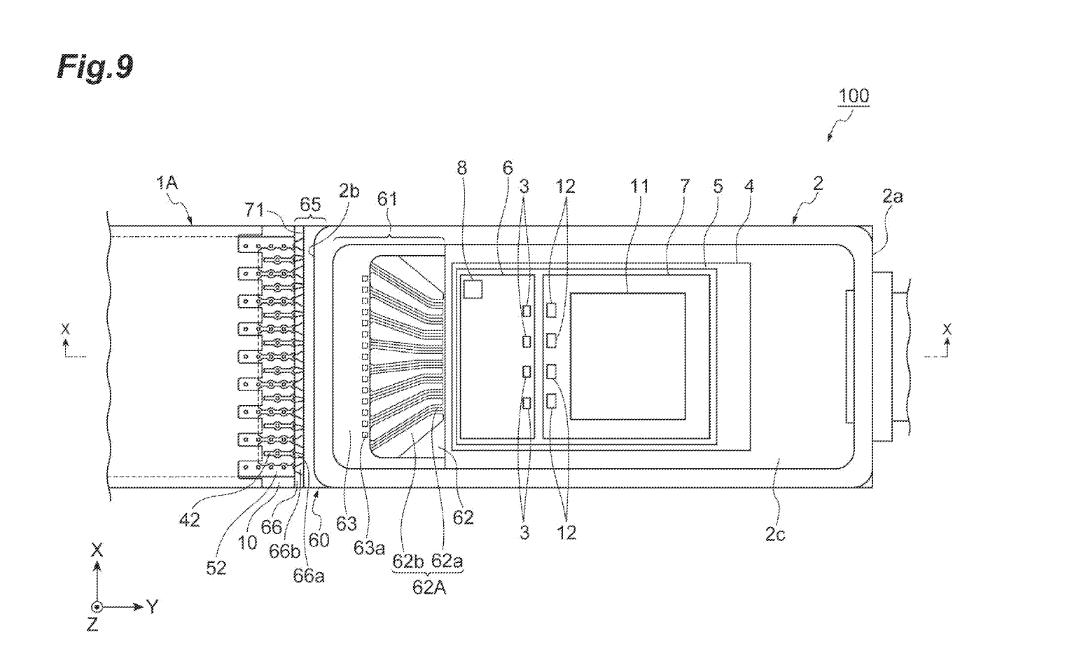

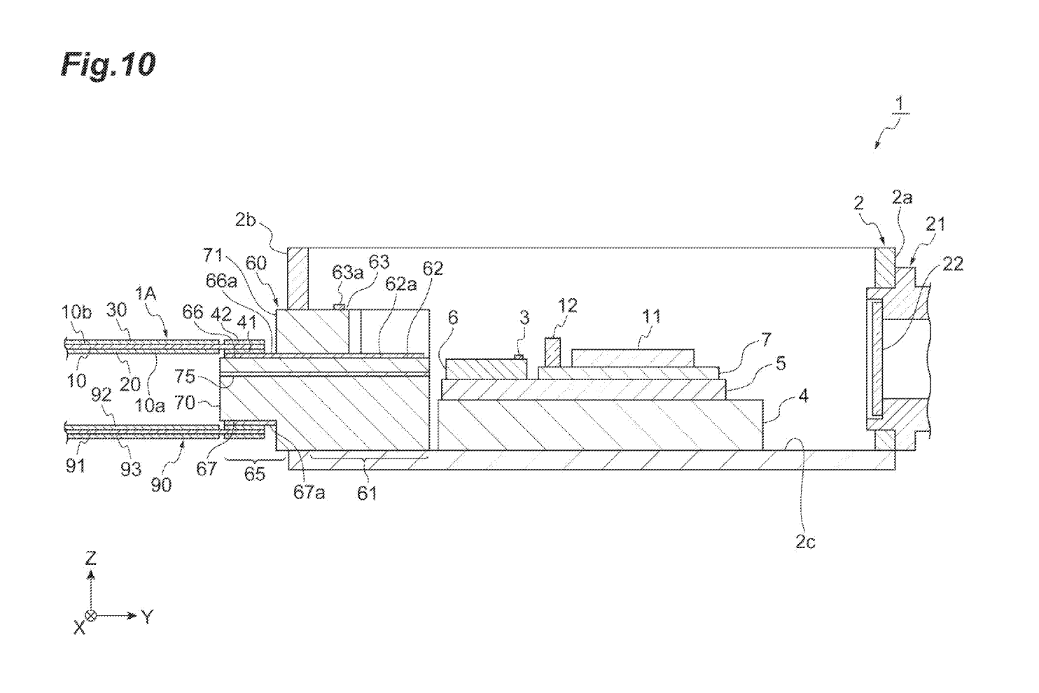

Next, a description is given of an example of an optical module including the flexible printed circuit board 1A described above. The embodiment illustrates a TOSA (Transmit Optical Sub-Assembly) type light-emitting module as an optical module. FIG. 8 is a plan view of an optical module 100 including the flexible printed circuit board 1A. FIG. 9 is a plan view illustrating an inner configuration of the optical module 100 without an upper lid of a chassis 2. FIG. 10 is a cross-sectional view along a line X-X illustrated in FIG. 9. Note that an XYZ orthogonal coordinate system is illustrated in each drawing for easy understanding. An X-axis is along the direction A2 and a Y-axis is along the direction A1. As illustrated in FIG. 8 to FIG. 10, the optical module 100 according to the embodiment includes, besides the flexible printed circuit board 1A, a chassis 2, an optical output port 21 (see FIG. 8), a feed-through 60, and a flexible printed circuit board 90 (see FIG. 10).

The chassis 2 has a rectangular parallelepiped shape extending in a Y direction. The chassis 2 has side walls 2a and 2b facing each other in the Y direction, and a bottom surface 2c intersecting a Z direction. The side walls 2a and 2b are along an X direction. The bottom surface 2c is in contact with lower ends of the side walls 2a and 2b in the Z direction. The chassis 2 houses N/2 (e.g., four) laser diodes (LDs) 3 as optical elements. The LDs 3 are arranged on the bottom surface 2c to be aligned along the X direction. For example, in a case that each LD 3 is a direct modulation type LD, optical intensity modulation of a laser light is performed depending on a modulated current signal applied via the flexible printed circuit board 1A. A wavelength of each laser light consists of four different wavelengths standardized by the MSA.

The chassis 2 houses a thermal electric cooler (TEC) 4, a base 5, carriers 6 and 7, a thermistor 8, an optical multiplexer 11, and (N/2) lenses 12. The TEC 4 is mounted on the bottom surface 2c. A voltage applied to the TEC 4 is controlled such that a value of resistance obtained from the thermistor 8 is a constant value, and such that temperatures of the LDs 3 are constant to control the wavelengths of the laser lights generated in the LDs 3. The base 5 is constituted by a material having high thermal conductivity, for example, aluminum nitride, with which heat influx by the TEC 4 can be efficiently performed. The base 5 is mounted on the TEC 4. The carriers 6 and 7 are mounted on the base 5. The carrier 6 is an external board in the embodiment, and is constituted by a material having high thermal conductivity, for example, aluminum nitride, with which a heat generated in the LD 3 can be efficiently diffused. The carrier 7, which mounts thereon parts not involving heat generation such as the lens 12 and the optical multiplexer 11, is constituted by aluminum nitride or alumina, for example. The LDs 3 and the thermistor 8 are mounted on the carrier 6. The thermistor 8 detects a surrounding temperature of each LD 3. On the carrier 6, mounted are a plurality of interconnections electrically connecting respectively with a plurality of LDs 3 through a bonding wire, for example. A plurality of interconnections are provided to transmit modulated signals applied through the flexible printed circuit board 1A to a plurality of LDs 3.

The carrier 7 is arranged between the carrier 6 and the side wall 2a in the Y direction. The lenses 12 and the optical multiplexer 11 are mounted on the carrier 7. The lenses 12 are arranged to correspond respectively to the LDs 3, and optically coupled with the LDs 3. Each lens 12 parallelizes a laser light output from each LD 3. The optical multiplexer 11 is arranged on a light path between the lenses 12 and the optical output port 21 in the Y direction. The optical multiplexer 11 is optically coupled with the lenses 12, and multiplexes (N/2) laser lights different in the wavelength which are parallelized by the lenses 12. The laser lights (parallel lights) multiplexed by the optical multiplexer 11 are output outside of the optical module 100 via the optical output port 21.

The optical output port 21 has a columnar shape extending along the Y direction. A part of the optical output port 21 is embedded in the side wall 2a. In that part, an optical window 22 is housed as illustrated in FIG. 10. The optical window 22 is optically coupled with the optical multiplexer 11. The rest of the optical output port 21 is positioned outside of the side wall 2a in the Y direction. That rest holds a lens and an optical fiber which are optically coupled with the optical window 22. The laser lights (parallel lights) output from the optical multiplexer 11 are collected by a lens arranged before the optical fiber and input to the optical fiber. The laser lights are supplied to the outside of optical module 100 through the optical fiber.

The feed-through 60 is provided to electrically connect an inside of the side wall 2b with an outside thereof. The feed-through 60 is arranged on the bottom surface 2c, and extends from the inside to the outside of the side wall 2b along the Y direction. The feed-through 60 is constituted by ceramic containing alumina, for example. The feed-through 60 has an inner structure 61 provided inside the side wall 2b, an outer structure 65 provided outside the side wall 2b, and a ground pattern 75 which is formed on from the inner structure 61 to the outer structure 65 in an XY plane and defines a reference potential.

The inner structure 61 includes top surfaces 62 and 63 intersecting the Z direction. The top surfaces 62 and 63 are positioned inside the side wall 2b in the Y direction. The top surface 62 includes a transmission line 62A to transmit the modulated signal applied through the flexible printed circuit board 1A to each LD 3 (see FIG. 9). The transmission line 62A includes N signal interconnections 62a electrically connecting with the LDs 3, and (N+1) ground interconnections 62b defining the reference potential. The signal interconnections 62a and the ground interconnections 62b extend along the Y direction. The signal interconnections 62a and the ground interconnections 62b are alternately aligned along the X direction. In the embodiment, one differential signal interconnection is configured every two signal interconnections 62a. The differential signal interconnection is provided to correspond to each LD 3. The differential signal interconnections and the ground interconnections 62b connect with the interconnections on the carrier 6 through a bonding wire, for example. Therefore, each of the differential signal interconnections electrically connects with the corresponding LD 3 through the bonding wire and the interconnections on the carrier 6. The top surface 63 includes a plurality of terminals 63a including a power interconnection and an analog signal interconnection. The terminals 63a electrically connect with the thermistor 8, the TEC 4, and the like through the bonding wire.

The outer structure 65 includes a top surface 66 perpendicular to the Z direction, a back surface 67 opposed to the top surface 66 in the Z direction, a rear surface 70 arranged opposite to the inner structure 61 with respect to the side wall 2b in the Y direction, and a rear surface 71 arranged between a plane including the rear surface 70 and a plane including the side wall 2b in the Y direction.

The top surface 66 is positioned outside the side wall 2b in the Y direction. The top surface 66 includes N signal lines 66a and (N+1) ground lines 66b. The signal lines 66a and the ground lines 66b extend along the Y direction. The signal line 66a and the ground lines 66b are alternately aligned along the X direction. Specifically, two ground lines 66b are arranged on both sides of one signal line 66a in the X direction. The signal lines 66a electrically connect with the signal interconnections 62a on the top surface. The ground lines 66b define the reference potential and electrically connect with the ground interconnections 62b.

The back surface 67 includes a plurality of pads 67a including a power pad and an analog signal pad (see FIG. 10). Each pad 67a electrically connects with each terminal 63a through a via, for example. The ground pattern 75 includes a portion positioned between the top surface 66 and the back surface 67 in the Z direction, and are along the top surface 66 and the back surface 67. The ground pattern 75 electrically connects with ground lines 66b through a via.

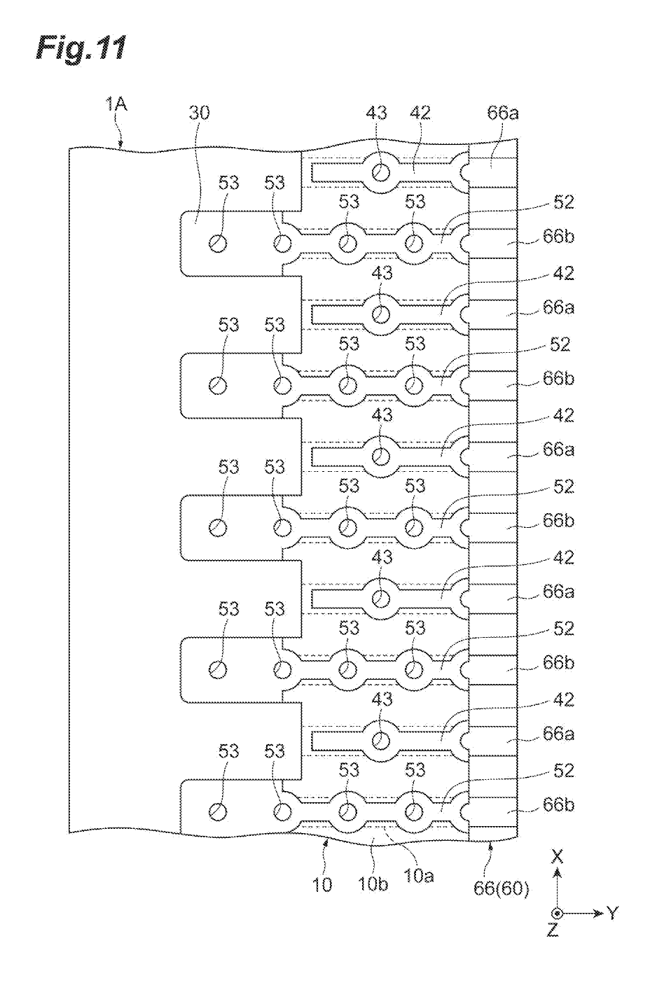

FIG. 11 is a plan view enlargedly illustrating a connecting portion of the flexible printed circuit board 1A and the feed-through 60. As illustrated in FIG. 10 and FIG. 11, the top surface 10a of the flexible printed circuit board 1A is opposed to the top surface 66 in the Z direction. Then, the signal terminals 41 and the ground terminals 51 of the flexible printed circuit board 1A, and the signal lines 66a and the ground lines 66b of the feed-through 60 stack one another in the Z direction. The signal terminals 41 connect with the signal lines 66a via an electrically conductive adhesive such as solder paste. The ground terminals 51 connect with the ground line 66b via an electrically conductive adhesive such as solder paste. The flexible printed circuit board 1A applies the modulated signals to the LDs 3 through the signal lines 20 and the signal terminals 41.

As illustrated in FIG. 10, the flexible printed circuit board 90 has a flexible substrate 91, a plurality of interconnections 92 provided on one surface of the substrate 91, and a plurality of interconnections 93 provided on the other surface of the substrate 91. One surface of the flexible printed circuit board 90 is opposed to the back surface 67 in the Z direction. A plurality of interconnections 92 and 93 are connected respectively to a plurality of terminals provided to one end of the substrate 91, and the terminals connect with the pads 67a via an electrically conductive adhesive such as solder paste. The flexible printed circuit board 1A applies the modulated signals to the LDs 3 through N signal lines 20. The flexible printed circuit board 90 applies control signals to the thermistor 8, the TEC 4, and the like through a plurality of interconnections 92 and 93.

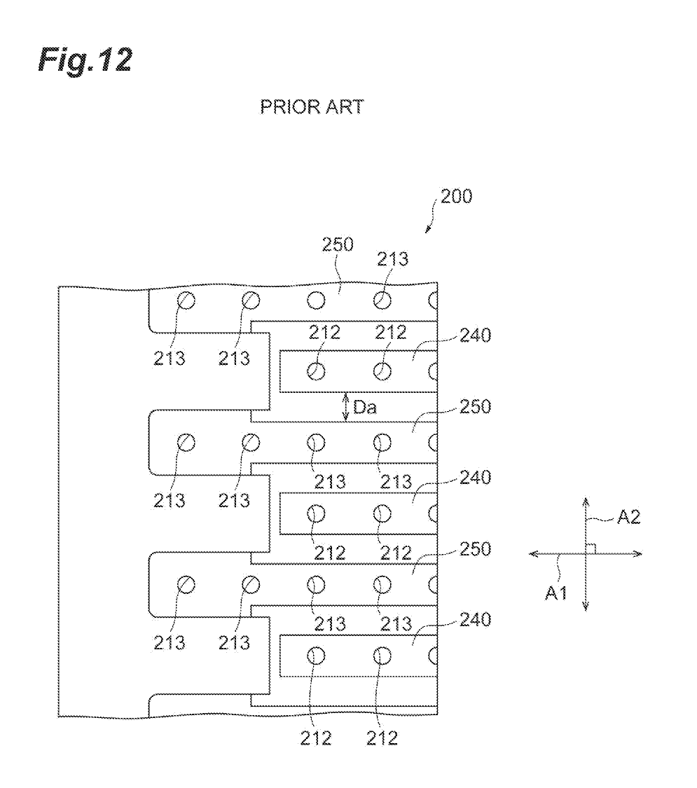

A description is given of effects obtained by the flexible printed circuit board 1A according to the embodiment. FIG. 12 is a plan view illustrating an end portion (connecting part) of a flexible printed circuit board 200 of prior art. In the connecting part of the flexible printed circuit board 200, signal terminals 240 and ground terminals 250 are alternately arranged to be aligned in the second direction A2. Each signal terminal 240 has a plurality of via holes 212 arranged along the first direction A1, and each ground terminal 250 has a plurality of via holes 213 arranged along the first direction A1. If an interconnection density of the signal lines in the flexible printed circuit board 200 increases as the electrical equipment is reduced in size and complexed, a distance Da between the signal terminal 240 and the ground terminal 250 in the connecting part is narrowed. If the distance Da between the signal terminal 240 and the ground terminal 250 is narrowed, a coupling capacitance of the signal terminal 240 and the ground terminal 250 increases to lead to decrease in a characteristic impedance. If the characteristic impedance is decreased, a high frequency characteristic of the flexible printed circuit board 200 is degraded to attenuate the signal.

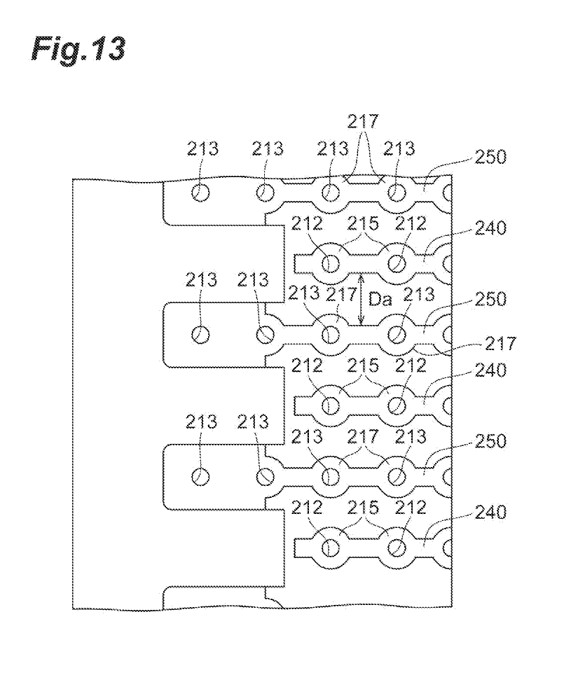

In order to prevent the coupling capacitance from increasing while a pitch (distance between centers) of the signal terminal 240 and the ground terminal 250 is maintained, it is effective to thin a width of a conductive film for each of the signal terminal 240 and the ground terminal 250 to widen the distance Da between the signal terminal 240 and the ground terminal 250, as illustrated in FIG. 13. However, the via holes 212 and 213 need to have a certain size of inner diameter so that a metal as the conductive film is easily inserted into an inner side. An area having a certain size of width (land 215 or 217) from the inner wall of the via hole 212 or 213 is secured for the conductive film provided around the via hole 212 or 213. If a distance between the land 215 on the signal terminal 240 and the land 217 on the ground terminal 250 is shorter, the whole coupling capacitance cannot be sufficiently suppressed due to capacitive coupling of these lands 215 and 217.

It can be considered that the signal terminal and the ground terminal are arranged in a staggered arrangement of two rows back and forth as in Japanese Unexamined Patent Publication No. 2015-216385. However, such an arrangement may be difficult since a dimension in back and forth directions of a connected target of the flexible printed circuit board (the optical module 100 in the embodiment) is restricted, for example.

In order to address such a problem, in the flexible printed circuit board 1A in the embodiment, positions of the via hole 43 on the signal terminals 41 and 42 and the via hole 53 on the ground terminals 51 and 52 are displaced from each other in the first direction A1. This can make the distances D1 to D4 between the lands 44 and 45, and the lands 54 and 55 be longer to decrease the coupling capacitance of the lands. Therefore, according to the flexible printed circuit board 1A in the embodiment, it is possible to prevent the increase in the coupling capacitances of the signal terminals 41 and 42, and the ground terminals 51 and 52 which is involved by the increase in the interconnection density of the signal lines 20, and effectively suppress decrease in the characteristic impedance.

The via hole 43 on the signal terminals 41 and 42, and the via hole 53 on the ground terminals 51 and 52 may be alternately arranged (alternated with each other) in the first direction A1. This allows the lands 44 and 45 and the lands 54 and 55 to be arranged away from each other to prevent a short caused by contacting. Moreover, in this case, the distances D1 to D4 between the land 44 (45) and the land 54 (55) next to the land 44 (45) may be equal to each other. This makes the distances between the lands be equal to each other and values of the capacitances be equal to each other, and then, the high frequency characteristic can be improved.

As in the embodiment, the number of via holes 43 on the signal terminal 42 may be less than the number of via holes 53 on the first ground terminal 52A and the number of via holes 53 on the second ground terminal 52B. In the signal line, the smaller a change in the thickness, the more a variation in the characteristic impedance is suppressed. Specifically, the fewer the number of via holes 43, the better, in order to bring the thickness of the signal terminals 41 and 42 closer substantially to a constant. On the other hand, on the ground terminals 51 and 52, the more the number of via holes 53, the better, in order to steady potentials of the ground terminals 51 and 52.

The position of the via hole 53 on the first ground terminal 52A in the first direction A1 may match the position of the via hole 53 on the second ground terminal 52B in the first direction A1. This makes the distances between the respective via holes 53 on the first ground terminal 52A and second ground terminal 52B and the via hole 43 on the signal terminal 42 be equal to each other and values of the capacitances be equal to each other, and then, the preferable characteristic in terms of a high frequency can be obtained.

The plate 10 may have the cutouts 46 and 56. Since a fillet of an electrically conductive adhesive is formed on the end edge 10c of the plate 10 when the flexible printed circuit board 1A is connected to the feed-through 60, an adhesive strength between the flexible printed circuit board 1A and the feed-through 60 is increased. This can improve a reliability of the optical module 100.

The flexible printed circuit board and the optical module according to the disclosure are not limited to the embodiments described above, and other various modifications may be adopted. For example, the above embodiments illustrate the case that the number of via holes on each signal terminal is one, but the number of via holes on each signal terminal may be two or more. The above embodiments illustrate the light-emitting module as the application of the flexible printed circuit board, but the flexible printed circuit board can be applied to the light-receiving module and other various electronic equipment. The above embodiments illustrate the case that the light-receiving module includes two flexible printed circuit boards (i.e., the flexible printed circuit boards 1A and 90), but the electronic equipment such as the light-receiving module may include only one flexible printed circuit board. Accordingly, the present disclosure has a scope defined in the claims attached below and all modifications and the changes for elements recited in the claims and equivalents thereto.

What is claimed is:

1. A flexible printed circuit board comprising:
a board having a top surface and a back surface;
a signal line provided on the top surface of the board;
a ground line provided on the back surface and overlapping with the signal line;
a first signal terminal extending along a first direction in the top surface of the board, the first signal terminal including a first via-hole and electrically connected with the signal line;
a first ground terminal provided next to the first signal terminal along a second direction intersecting the first direction on the top surface of the board, the first ground terminal including a second via-hole electrically connected with the ground line in the back surface of the board; and
a second ground terminal provided next to the first signal terminal in a side opposite to the first ground terminal along the second direction on the top surface of the board, the second ground terminal including a third via-hole electrically connected with the ground line in the back surface of the board,
wherein the first to third via-holes are staggeringly disposed along the second direction.

2. The flexible printed circuit board of claim 1, further comprising:
a second signal terminal provided on the back surface of the board, the second signal terminal being electrically connected with the first signal terminal via the first via-hole;
a third ground terminal provided next to the second signal terminal on the back surface of the board in a side of the first ground terminal against the first signal terminal, the third ground terminal being electrically connected with the first ground terminal in the top surface of the board via the second via-hole; and
a fourth ground terminal provided next to the second signal terminal on the back surface of the board in the side of the second ground terminal with respect to the first signal terminal, the fourth ground terminal being electrically connected with the second ground terminal via the third via-hole.

3. The flexible printed circuit board of claim 2,
wherein the first via-hole accompanies a first land; and
wherein the second and third via-holes each accompany a second land, and
wherein the first land makes a distance against the second land attributed in the second via-hole that is substantially equal to a distance from the first land to the second land attributed in the third via-hole.

4. The flexible printed circuit board of claim 1,
wherein the first via-hole and the second via-hole are arranged offset from each other along the first direction.

5. The flexible printed circuit board of claim 1,
wherein the first signal terminal includes two or more first via-holes, the first ground terminal includes two or more second via-holes, and the second ground terminal includes two or more third via-holes, and
whereon the first via-holes in a number thereof is fewer than a total number of the second via-holes and the third via-holes.

6. The flexible printed circuit board of claim 1,
wherein the second via-hole and the third via-hole are aligned along the second direction but offset from the first via-hole.

7. An optical module including the flexible printed circuit board of claim 1, the optical module comprising:
an optical element provided on a base;
interconnections provided on the base and electrically connected with the optical element on the base; and
a classis enclosing the base therein,
wherein the interconnections are divided into first to third groups, the first group of the interconnections being electrically connected with the first signal terminal, the second group of the interconnection being electrically connected with the first ground terminal, and the third group of the interconnection being electrically connected with the second ground terminal.
